(19) United States
(12) Patent Application Publication
(10) Pub. No.: US 2026/0050720 A1
(43) Pub. Date: Feb. 19, 2026

(54) PROACTIVE RESERVOIR SIMULATION

(71) Applicant: Schlumberger Technology Corporation, Sugar Land, TX (US)

(72) Inventors: Mohamed Osman Mahgoub Ahmed, Abu Dhabi (AE); Prakash Bajpai, Gurgaon (IN)

(21) Appl. No.: 19/301,112

(22) Filed: Aug. 15, 2025

Related U.S. Application Data
(60) Provisional application No. 63/683,337, filed on Aug. 15, 2024.

(51) Int. Cl. G06F 30/28

(52) U.S. Cl. CPC G06F 30/28

(57) ABSTRACT

A method for performing a reservoir simulation includes receiving input data. The method also includes generating one or more subsurface models based upon the input data. The method also includes training a first artificial intelligence (AI) model based upon the one or more subsurface models to produce a first trained AI model. The method also includes training a second AI model by hiding some of the input data to produce a second trained AI model. The method also includes training a third AI model to produce a third trained AI model. The third AI model is trained using simulation performance metrics from simulations performed to train the first AI model and the second AI model. The method also includes performing the reservoir simulation using the first trained AI model, the second trained AI model, and/or the third trained AI model.

### CROSS-REFERENCE TO RELATED APPLICATIONS

This application claims priority to and the benefit of U.S. Provisional Patent Application No. 63/683,337, filed on Aug. 15, 2024, which is incorporated by reference in its entirety.

### BACKGROUND

Reservoir simulation depends on user inputs for reservoir property definitions and field management and operating conditions. More particularly, field development planning aspects (e.g., determining the optimum number and type of wells, operating conditions, and reservoir management practices) may be defined, designed, and implemented by the users. The conventional role of the simulators is to forward predict reservoir performance given these user inputs. This is performed by running the simulation engine and dumping outputs at the user-specified time-steps/report-steps. The results are interpreted by the users and qualified/ranked based on a criterion (e.g., mismatch function for model calibration/history matching problems, techno-economic analysis in field development planning). The process is repeated until the desired outcome is achieved when a near-optimum solution can be reached. It is a CPU-intensive and time-consuming process due to the iterative nature of external optimization.

Despite the progress made in subsurface modelling (e.g., machine learning-assisted seismic interpretation, log QC, and ML-assisted history matching), many reservoir development decisions are taken by domain experts, designed manually, and optimized through trial and error. Intelligence can be added to next-generation reservoir simulators facilitated by the new technological advances in the field of generative artificial intelligence.

Therefore, what is needed is an improved system and method for simulating a reservoir.

### SUMMARY

A method for performing a reservoir simulation is disclosed. The method includes receiving input data. The method also includes generating one or more subsurface models based upon the input data. The method also includes training a first artificial intelligence (AI) model based upon the one or more subsurface models to produce a first trained AI model. The method also includes training a second AI model by hiding some of the input data to produce a second trained AI model. The method also includes training a third AI model to produce a third trained AI model. The third AI model is trained using simulation performance metrics from simulations performed to train the first AI model and the second AI model. The method also includes performing the reservoir simulation using the first trained AI model, the second trained AI model, and/or the third trained AI model.

A computing system is also disclosed. The computing system includes one or more processors and a memory system. The memory system includes one or more non-transitory computer-readable media storing instructions that, when executed by at least one of the one or more processors, cause the computing system to perform operations. The operations include receiving input data. The input data includes realistic reservoir and field data including well production data, pressure data, and/or field development history data related to active and decommissioned projects. The input data also includes realistic reservoir properties distribution data, fault data, well geometries data, completion data, fluid data, or core analysis data. The operations also include generating one or more subsurface models based upon the input data. The one or more subsurface models include a set of real and simulated subsurface models. The operations also include training a first artificial intelligence (AI) model based upon the one or more subsurface models to produce a first trained AI model. The first AI model is trained based upon data generated by the real and simulated subsurface models. The operations also include training a second AI model to produce a second trained AI model. The second AI model is trained by hiding some of the input data. The operations also include training a third AI model to produce a third trained AI model. The third AI model is trained using simulation performance metrics from simulations performed to train the first AI model and the second AI model. The operations also include performing the reservoir simulation using the first trained AI model, the second trained AI model, and the third trained AI model.

A non-transitory computer-readable medium is also disclosed. The medium stores instructions that, when executed by one or more processors of a computing system, cause the computing system to perform operations. The operations include receiving first input data. The first input data includes user manuals, technical descriptions, sample reservoir simulation input files, and sample reservoir simulation output files. The operations also include tuning a large language model (LLM) based upon the first input data to produce a tuned LLM. The LLM is tuned to develop natural language support for interactivity with a reservoir simulation engine. The operations also include receiving second input data. The second input data includes realistic reservoir and field data including well production data, pressure data, and field development history data related to active and decommissioned projects. The second input data also includes realistic reservoir properties distribution data, fault data, well geometries data, completion data, fluid data, and core analysis data. The operations also include generating one or more subsurface models using the tuned LLM based upon the second input data. The one or more subsurface models include a set of real and simulated subsurface models. The simulated subsurface models are generated using a generative adversary network (GAN) model or other artificial intelligence techniques. The operations also include training a first artificial intelligence (AI) model based upon the one or more subsurface models to produce a first trained AI model. The first AI model is trained based upon data generated by the real and simulated subsurface models. The first AI model is trained with different field development options using gamified reinforcement learning. The different field development options include adding infill production and/or injection wells, testing workover options through completion zone shut-offs or new zone perforations, and optimizing production and injection rates. The operations also include training a second AI model to produce a second trained AI model. The second AI model is trained by hiding some of the second input data. The operations also include training a third AI model to produce a third trained AI model. The third AI model is trained using simulation performance metrics from simulations performed to train the first AI model and the second AI model. The simulation performance metrics include a total time of the simulations, an average length of time-steps in the simulations, a number of chopped time-steps in the simulations, and a total number of linear and nonlinear iterations of the simulations. The operations also include performing the reservoir simulation using the first trained AI model, the second trained AI model, and the third trained AI model. The reservoir simulation performed by the first trained AI model generates autonomous field development output used for production forecasting, increasing production, and/or cost reduction. The reservoir simulation performed by the second trained AI model uses results of the one or more subsurface models that are obtained using gamified reinforcement learning to generate history matching results and/or minimize a mismatch between the results of the one or more subsurface models and corresponding measured results. The reservoir simulation performed by the third trained AI model generates reservoir convergence criteria to increase a speed of the reservoir simulation without compromising accuracy. The reservoir convergence criteria includes dynamic changing of error tolerances for numerical solutions to be accepted including a maximum fluid saturation and composition change, a maximum pressure change, and a maximum time truncation error.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a schematic view of a reservoir simulation optimization loop, according to an embodiment.

FIG. 3A illustrates a schematic view of a global optimizer, and FIG. 3B illustrates a schematic view of a local optimizer, according to an embodiment.

FIG. 4 illustrates a schematic view of cloud computing and machine learning-assisted optimization of numerical simulations, according to an embodiment.

FIG. 5 illustrates a schematic view of components of a flexible reservoir management tool, according to an embodiment.

FIG. 6A illustrates a screenshot of the interactive reservoir simulation performing request callback as well as starting and terminating interactive sessions, according to an embodiment. FIG. 6B illustrates a screenshot of the interactive reservoir simulation executing Python code during an interactive session, according to an embodiment. FIG. 6C illustrates a screenshot of the interactive reservoir simulation listing available nodes during an interactive session, according to an embodiment.

FIG. 7 illustrates a table showing a user-defined action (e.g., using Python code) versus the corresponding natural language equivalent, according to an embodiment.

FIG. 8 illustrates a schematic view of a process of collecting realistic reservoir definitions and fluid and rock properties from corporate and public datasets, according to an embodiment.

FIGS. 9A and 9B illustrate graphs showing AI model prediction of well performance metrics iWOPT for production wells (FIG. 9A) and iWWIT for injection wells (FIG. 9B), according to an embodiment.

FIGS. 10A and 10B illustrate schematic views of a proactive simulation, according to an embodiment.

FIG. 11 illustrates a flowchart of a method for performing a proactive reservoir simulation, according to an embodiment.

FIG. 12 illustrates a graph showing clustering based on core data, according to an embodiment.

FIG. 13 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

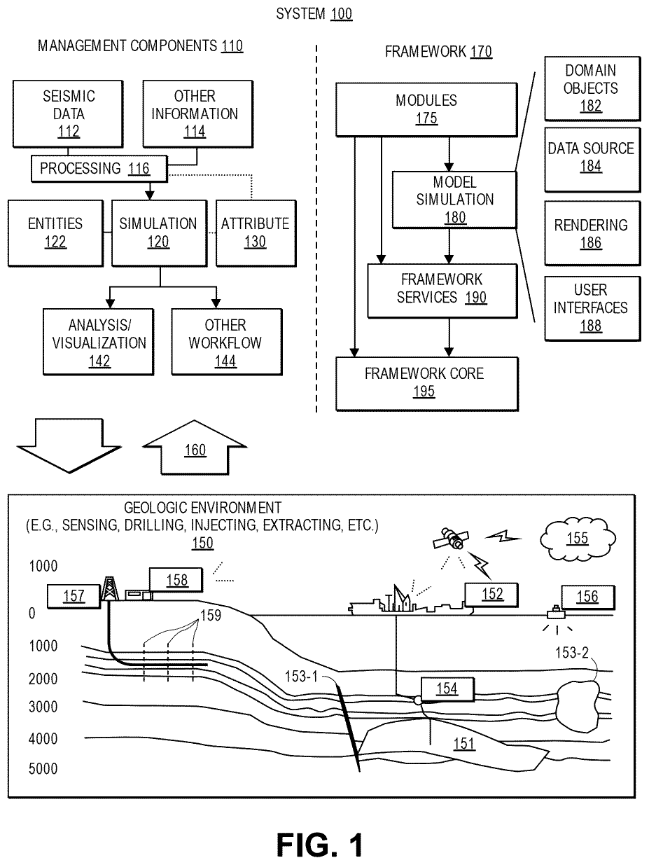

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (SLB, Houston Texas), the INTERSECT™ reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

As an example, the simulation component 120 may include one or more features of a simulator such as SYMMETRY™ software (SLB, Houston, Texas). More particularly, SYMMETRY™ may process workflows in a single integrated environment with accurate thermodynamic fluid representation and consistent modeling across multiple disciplines including process, production, and HSE. The simulator integrates steady-state and transient (e.g., dynamic) analyses that can be tailored for each domain. This approach enables users to optimize processes in upstream, midstream, and downstream sectors while maximizing profits and minimizing capital expenditures. It may also help reduce emissions, energy consumption, and waste.

As an example, the simulation component 120 may include one or more features of a simulator such as PIPESIM™ (SLB, Houston, Texas). More particularly, PIPESIM™ is steady-state multiphase flow simulator that incorporates the three areas of flow modeling: multiphase flow, heat transfer and fluid behavior.

As an example, the simulation component 120 may include one or more features of a simulator such as OLGA™ (SLB, Houston, Texas). More particularly, OLGA™ is a dynamic multiphase flow simulator that models transient flow (e.g., time-dependent behaviors) to maximize production potential. Transient modeling is a component for feasibility studies and field development design. Dynamic simulation is useful in deep water and is used in both offshore and onshore developments to investigate transient behavior in pipelines and wellbores. Transient simulation with the OLGA™ simulator provides an added dimension to steady-state analysis by predicting system dynamics, such as time-varying changes in flow rates, fluid compositions, temperature, solids deposition, and operational changes.

In an example embodiment, the management components 110 may include features of a commercially available framework such as the PETREL® seismic to simulation software framework (SLB, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (SLB, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

### Proactive Reservoir Simulation

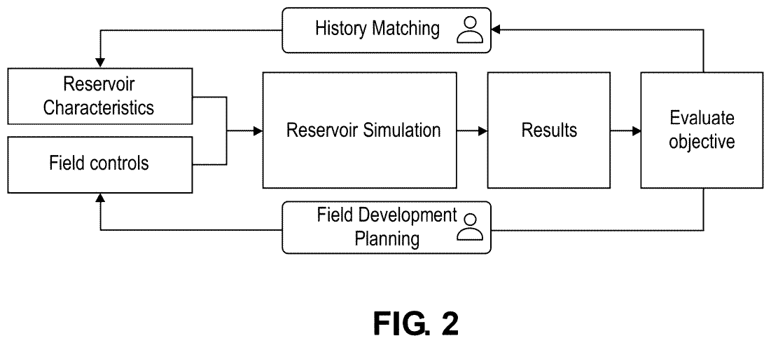

The present disclosure includes a system and method configured to perform reservoir simulation optimization loops during model calibration (e.g., history matching) or in field development planning are time-consuming tasks. FIG. 2 illustrates a schematic view of a reservoir simulation optimization loop, according to an embodiment.

History matching is an inverse process in which the reservoir input is changed to match field production and observations. Field development planning aims to modify (e.g., optimize) field controls (e.g., number of wells, recovery mechanism, etc.) to maximize field yields such as field recovery and net present value (NPV). Although the optimization process can be automated, the design of the optimization loops is largely a manual process where users select the type of parameters and their value range based on experience. The reservoir simulation and results boxes represent the reservoir simulator role, the reservoir characteristics, field controls, and evaluate objective boxes represent the role of an external tool (e.g., a pre- and post-processor).

Simulators provide reactive heuristic optimization capabilities to mimic field controls such as setting economic conditions to operate a well based on maximum water-cut, gas-oil-ratio or a minimum oil production rate. These reactive controls may achieve local optima without iterations. However, the reservoir management strategy itself can be the subject of optimization. For example, “what is the optimum maximum water-cut?” Shutting a well based on water production may reduce the cost by eliminating processing of the water production. It does, however, reduce the amount of oil production and therefore the revenue. Another example is the formulae used to allocate field production to individual wells (e.g., guide-rate). In conclusion, while reactive optimization substantially eliminates the use of additional simulation cases, some level of optimization is still used to optimize the cut-off values that define the reservoir management strategy.

Instantaneous optimization has grown in sophistication to address new reservoir control capabilities such as gas lift allocation and lower completion flow control valves optimization. In gas lift optimization, the objective is to maximize the utilization of available gas by using it in the most effective wells. The allocation of lift gas to individual wells follows an iterative process where reservoir and well flow models are evaluated within the timestep to maximize the oil production gain. The controls are set, and results evaluated, as part of the nonlinear iteration during a timestep solve. Advanced completions optimizers have recently been integrated into reservoir simulation to enable periodic valve choke adjustments to control horizontal and multilateral wells equipped with intelligent devices.

### Global and Local Optimizers

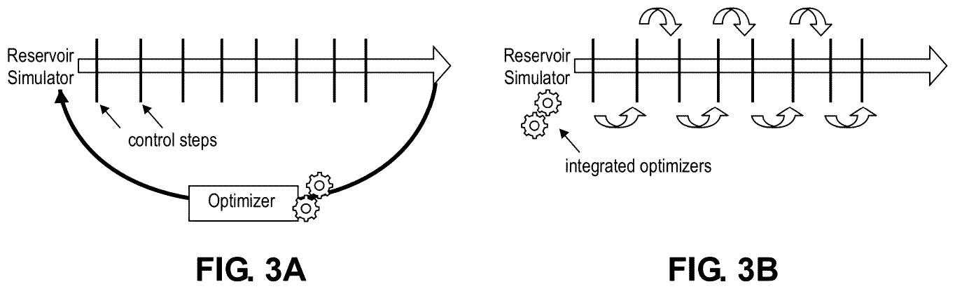

FIG. 3A illustrates a global optimizer, and FIG. 3B illustrates a local optimizer, according to an embodiment. The global vs. local optimization method differ in the optimization cycle and the number of parameters to be considered during optimization. Regular repetitive tasks may be better handled through local optimization where the optimization cycles are much shorter and faster. In the absence of local optimizers, the problem may involve multiple entire simulation iterations. For problems such as highly frequent completion optimization, local optimization has an advantage compared to global optimization due to the large number of optimization parameters and the long optimization cycle. However, in local optimization, the evaluation of objectives is instantaneous—meaning a well is shut/valves are adjusted based on the conditions at a specific time. The decision to shut the well/actuate the valve may result in short lived production enhancements but may not lead to a global optimum. Big decisions are usually evaluated using a global objective such as the final hydrocarbon/energy recovery, storage capacity and net present value (NPV).

Cloud computing and machine learning algorithms have the tendency to capture complex input-output relationships. They make a good representation of the subsurface models that can be used to fast-track the reservoir simulation optimization cycle. The advantage with cloud elasticity is the parallelization of the numerical simulations in a front-loaded workflow. The input and output data may then be used to train a machine learning model. Optimization on the machine learning model is very fast (e.g., 10,000,000 evaluations can be performed in a few seconds). While the number of simulations for optimization may have increased to have enough data to train machine learning models, the combination of cloud computing and machine learning can reduce the time to calibrate simulation models and optimize field development plans.

### Cloud Computing and ML-Assisted Optimization

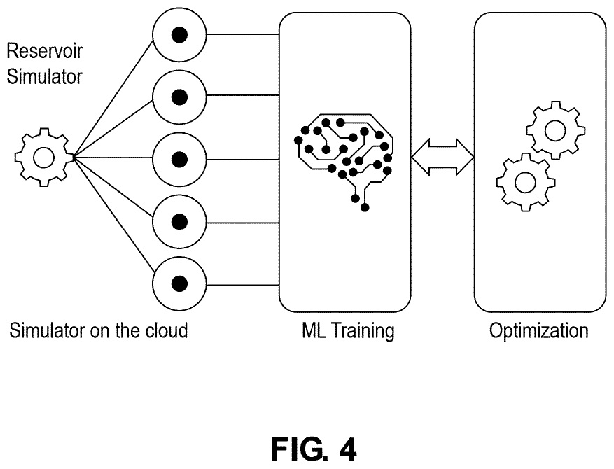

FIG. 4 illustrates a schematic view of cloud computing and machine learning-assisted optimization of numerical simulations, according to an embodiment. A development towards intelligent reservoir simulators is to have a framework to extend the field control logic. The field management actions can be encapsulated in instructions with triggering and stopping criteria that can be governed using time, budget, and/or resource availability. The tool can apply controls at different hierarchies (e.g. reservoir, completion, well, pumps, sensors, gathering station, and field levels). Mathematical expressions, static and dynamic lists of flow entities in addition to programming language (e.g., Python) support provide users with the flexibility to extend reservoir simulators capabilities and capture realistic field development strategies.

### Components of Flexible Reservoir Management Tool

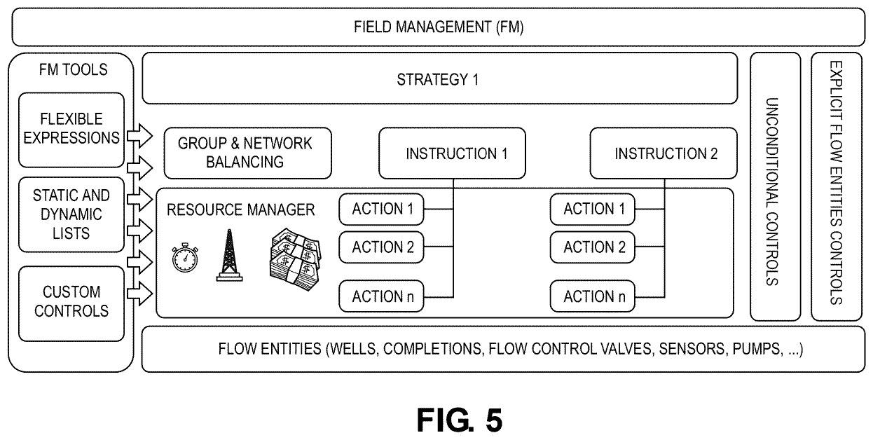

FIG. 5 illustrates a schematic view of components of a flexible reservoir management tool, according to an embodiment.

Conventional reservoir simulation: In a conventional reservoir simulation workflow, the users specify the type and frequency of output before running the simulation. The initially set field development plan and controls can be updated in a new simulation run. Runs can be stopped or restarted, and a new case can be defined based on the results of the base case.

Interactive reservoir simulation: The next-generation reservoir simulators are built as interactive in nature. That is, the allow users to query the results dynamically as the simulation progresses through call back functions through a flexible and extensible simulation management tool.

### Examples of Interactive Reservoir Simulation

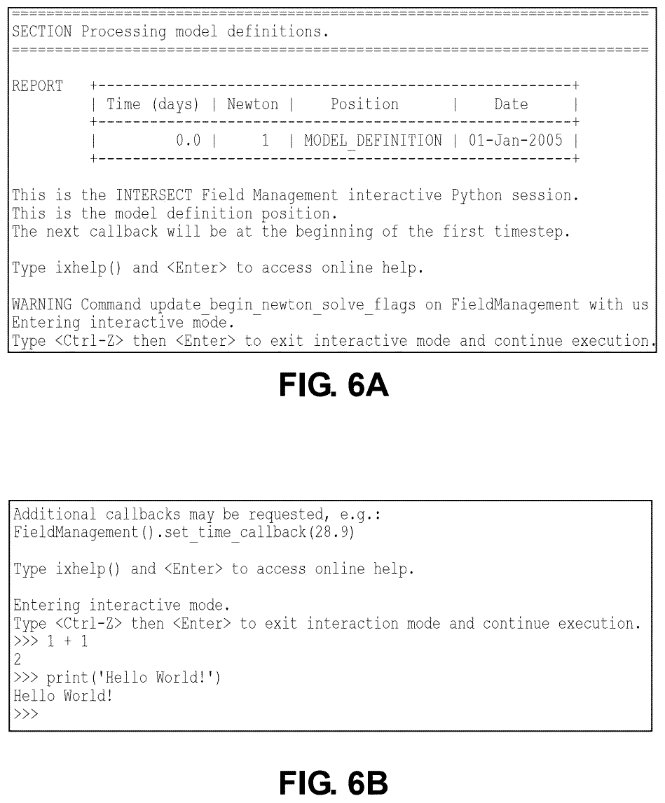

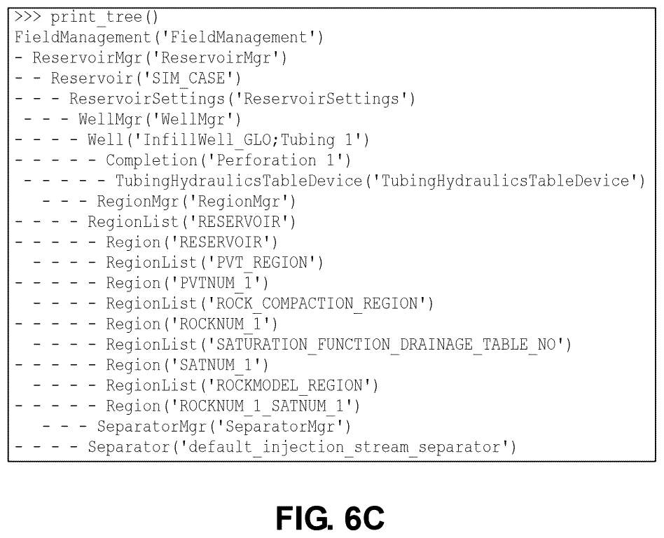

FIG. 6A illustrates a screenshot of the interactive reservoir simulation performing request callback as well as starting and terminating interactive sessions, according to an embodiment. Intersect is an example of the reservoir simulator that is described.

FIG. 6B illustrates a screenshot of the interactive reservoir simulation executing Python code during an interactive session, according to an embodiment. Intersect is an example of the reservoir simulator that is described.

FIG. 6C illustrates a screenshot of the interactive reservoir simulation listing available nodes during an interactive session, according to an embodiment. Intersect is an example of the reservoir simulator that is described.

The present disclosure includes a proactive reservoir simulation system and method that form an extension to the next-generation reservoir simulators. The system and method may use, for example:
1. Domain specific tuning of Large Language Models (LLM) to develop a natural language support for interactivity with reservoir simulation engines.
2. Generative Adversary Networks (GAN) models to create realistic subsurface models.
3. Gamified reinforcement learnings to train the proactive model as an additional layer that is independent of the routines of conventional reservoir simulators but can communicate through the advanced field management protocols with core simulators and through natural language with users. This may be used for at least three cases:
   a. Fully automatic model calibration (History matching) through auto parameterization
   b. Automatic optimization of field development plans
   c. Automatic and dynamic tuning of numerical convergence parameters

The development of this proactive layer can revolutionize the use of reservoir simulation as it enables the automation of the most time-consuming elements of field development planning activities.

The advent of Generative Artificial Intelligence (GenAI) brought forth opportunities to add intelligence to revolutionize the role of reservoir simulators from reactive and interactive to a proactive reservoir calibration and optimization tool. This development has several components.

### User-Defined Action Versus Natural Language Equivalent

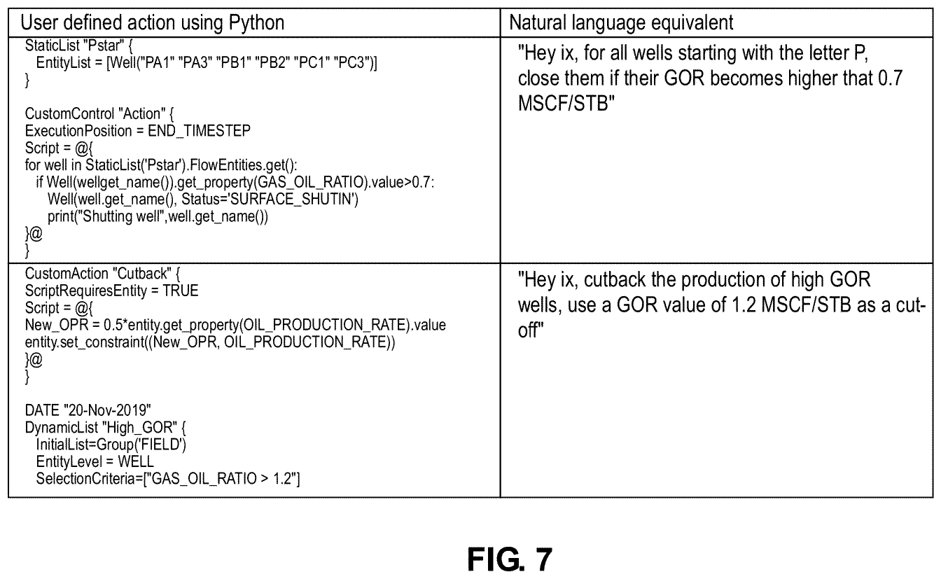

The tuning of Large Language Models (LLMs) to enhance the communication experience. Instead of writing (e.g., Python) code to query and set properties, users can use natural language. FIG. 7 illustrates a table showing a user-defined action (e.g., using Python code) versus the corresponding natural language equivalent, according to an embodiment.

### Collecting Reservoir Definitions and Fluid and Rock Properties

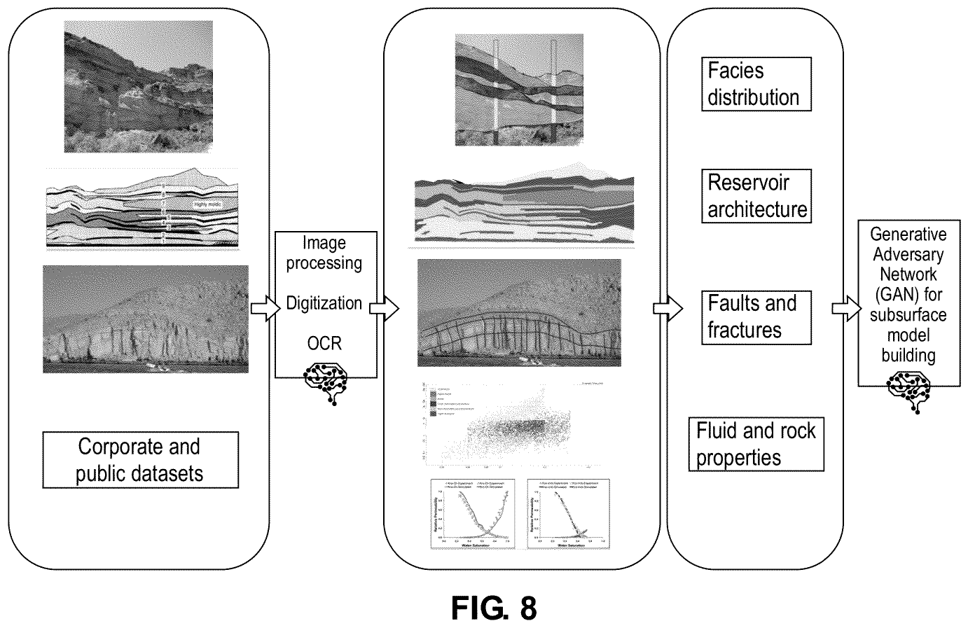

The application of GenAI for realistic and random reservoir models generation. The models can be used as testing grounds for model calibration, production optimization and numerical convergence studies. FIG. 8 illustrates a schematic view of a process of collecting realistic reservoir definitions and fluid and rock properties from corporate and public datasets, according to an embodiment. New technologies such as digitization, image processing, OCR, etc. can help structure the input dataset that can feed GAN models to generate realistic subsurface models.

Train an AI model using self-play reinforcement learning. Examples of the AI model may be or include Intersect (IX), Eclipse, etc. This may be done through the gamification of model calibration, field development planning, and numerical convergence.

Model calibration involves decisions on the type and value range of input parameters that can be changed. Some input parameters may be measured to a high degree of confidence, and those should not be altered. Other parameters can be perturbed to achieve history matching results. The gamification process starts with a realistic model being built using GAN (e.g., the previous step). The steps for reinforcement learning are, for example, as follows:
(1) The simulator can be used to forward predict the reservoir performance given the initial and boundary conditions. The results of the simulation may be recorded.
(2) Hide the input and seed parameters that were used in the initial simulation, generate ensemble of new reservoir models, and start the reservoir calibration process by varying the alterable reservoir parameters. Record the new forward simulation results and compare with the results from the hidden model (e.g., calculate mismatch on a well-by-well basis).
(3) Relating the loss function to the calculated mismatch. The model is trained to identify which parameters to select for model calibration, and the value ranges to be considered may be compared to their initial parameter values.

Field development planning involves decisions related to adding development wells (e.g., their location, type) and defining the optimum operating conditions. Some decisions may be taken on the number of wells and the recovery mechanism (e.g., waterflooding, gas injection, water-alternating-gas injection (WAG), chemical enhanced oil recovery (EOR), etc. Conventionally, these decisions are tested manually by engineers using their domain expertise which can take a long time. The AI model may take into consideration the field development decisions. The timing of adding new wells and implementing these recovery mechanisms should also be considered.
(1) Start with generating a realistic subsurface model using GAN (the previous step)
(2) Run an ensemble of simulation models with different field development strategies.
(3) Score each forward model based on the final recovery or an economic metric such as the net-present-value.
(4) Repeat the process on different types of models. This may allow the AI model to develop the compatibility between reservoir characteristics and the best development plan.

### AI Model Prediction

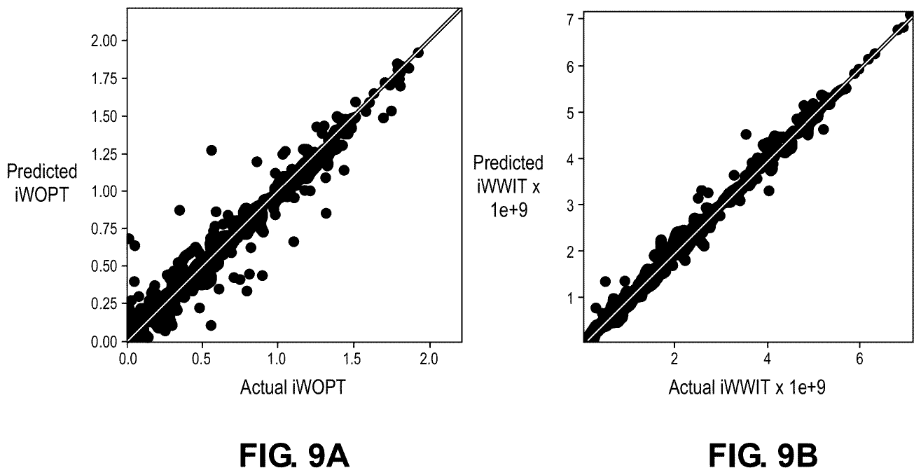

Large Language Models (LLMs) may be tuned enhance the communication experience. AI-enabled solutions for well placement using AI can be added as subcomponents of the proactive reservoir simulation layer to automate the well placement optimization and scheduling tasks. FIGS. 9A and 9B illustrate graphs showing AI model prediction of well performance metrics iWOPT for production wells (FIG. 9A) and iWWIT for injection wells (FIG. 9B), according to an embodiment. The graphs show that an AI model may predict the well performance given its location and completions specifications. The data shown in these graphs was not used in the training process of the AI model.

Numerical convergence parameter values can affect the CPU-time and therefore the cost of running reservoir simulation. This can have a greater impact on ensemble-based calibration and optimization runs on the cloud. Numerical convergence parameter selection can be related to the reservoir characteristics, the recovery mechanism, and/or the operating conditions. As these can change with time, dynamic assignment of convergence parameters is used for optimum results.

The simulation models run to train the AI model on model calibration and field development optimization can provide training data for numerical convergence. Develop models may be used to predict the reason for selecting time-step duration length. Develop models may be used to predict the time-step length itself given the operating conditions. Run differential simulation to study the impact of varying convergence parameters on the CPU-time and monitor the consistency of the results. The objective is to define the best tuning parameters that will minimize the CPU Time without noticeable changes in the results

### Implementation—Proactive Simulation

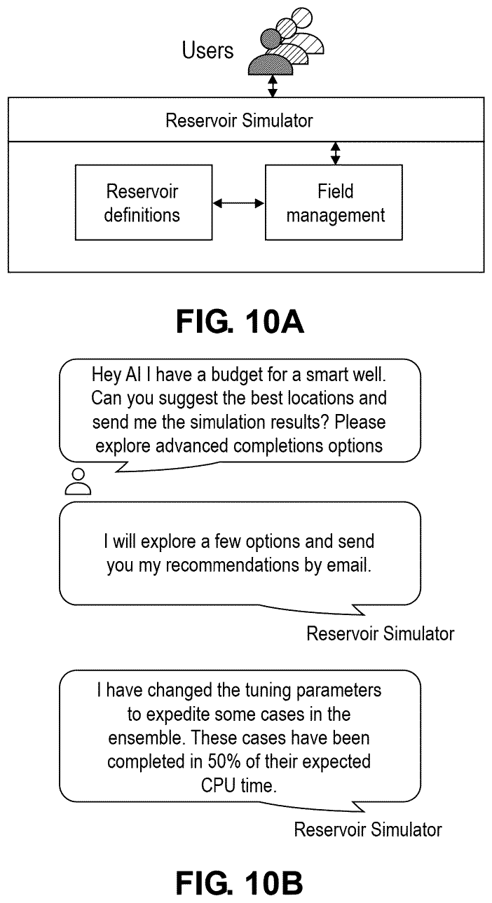

The AI model (e.g., Intersect, Eclipse, etc.) module can be developed as an external entity to the conventional reservoir simulation processes. The interaction between the AI model and reservoir simulator may be facilitated by the extensibility feature and interactive nature of the field management controller. FIGS. 10A and 10B illustrate schematic views of a proactive simulation, according to an embodiment.

Reservoir engineers spend time designing optimization tasks during model calibration (e.g., history matching) and field development planning. These involve special expertise and skill. The components described herein allow for an automation of model calibration and field development planning processes. Applications of the system and method described herein may include auto model calibration, auto field development optimization, and/or auto dynamic tuning of numerical convergence settings. The external proactive module can revolutionize the reservoir simulation workflow. It builds on a list of capabilities that Intersect has. A product incorporating the system and method may be able to use natural language support for user instructions making simulations easier. In addition, it would be possible for nonexperts to run simulations.

### Exemplary Method

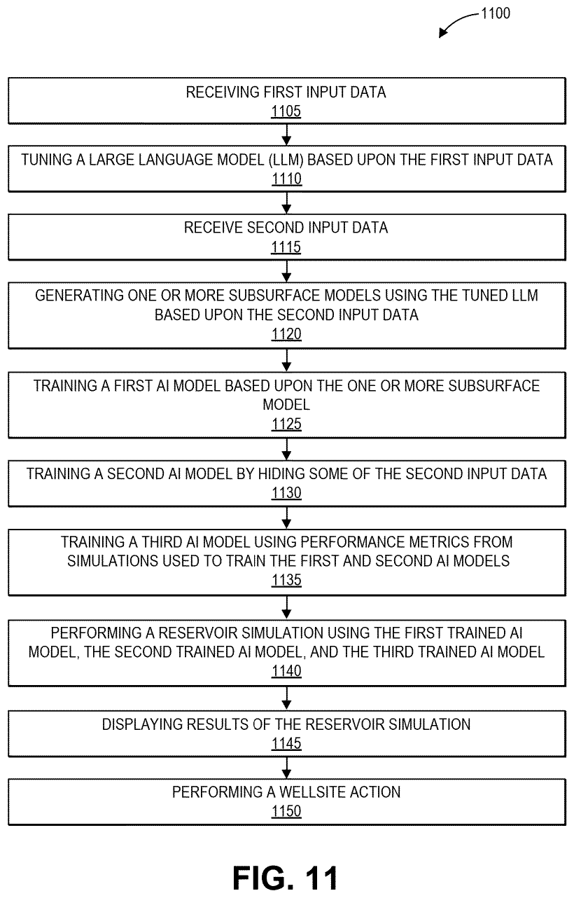

FIG. 11 illustrates a flowchart of a method 1100 for performing a proactive reservoir simulation, according to an embodiment. An illustrative order of the method 1100 is provided below; however, one or more portions of the method 1100 may be performed in a different order, simultaneously, repeated, or omitted. At least a portion of the method 1100 may be performed by a computing system (described below).

The method 1100 may include receiving first input data, as at 1105. The first input data may include user manuals, technical descriptions, sample reservoir simulation input files, sample reservoir simulation output files, or a combination thereof.

The method 1100 may also include tuning a large language model (LLM) based upon the first input data to produce a tuned LLM, as at 1110. The LLM may be tuned to develop natural language support for interactivity with a reservoir simulation engine (e.g., used by one or more AI models, which are described below).

The method 1100 may also include receiving second input data, as at 1115. The second input data may include realistic (e.g., measured or synthetic) reservoir and field data such as well production data, pressure data, field development history data related to active and decommissioned projects. The second input data may also or instead include realistic reservoir properties distribution data, fault data, well geometries data, completion data, fluid data, core analysis data, or a combination thereof.

The method 1100 may also include generating one or more subsurface models using the tuned LLM based upon the second input data, as at 1120. The one or more subsurface models may include a set of real and simulated subsurface models. The simulated subsurface models may be generated using a generative adversary network (GAN) model or other artificial intelligence techniques.

The method 1100 may also include training a first AI model based upon the one or more subsurface models to produce a first trained AI model, as at 1125. The first AI model may be trained based upon data generated by the real and simulated subsurface models. The first AI model may be trained with different field development options using gamified reinforcement learning. The different field development options may include adding infill production and/or injection wells, testing workover options through completion zone shut-offs or new zone perforations, optimizing production and injection rates, or a combination thereof.

The method 1100 may also include training a second AI model to produce a second trained AI model, as at 1130. The second AI model may be trained by hiding some of the second input data.

The method 1100 may also include training a third AI model to produce a third trained AI model, as at 1135. The third AI model may be trained using simulation performance metrics from simulations performed to train the first AI model and the second AI model. The simulation performance metrics may include a total time of the simulations, an average length of time-steps in the simulations, a number of chopped time-steps in the simulations, a total number of linear and nonlinear iterations of the simulations, or a combination thereof.

The method 1100 may also include performing the reservoir simulation using the first trained AI model, the second trained AI model, and/or the third trained AI model, as at 1140. The reservoir simulation performed by the first trained AI model may generate autonomous field development output used for production forecasting, increasing production, and/or cost reduction. The reservoir simulation performed by the second trained AI model may use results of the one or more subsurface models (e.g., that are obtained using gamified reinforcement learning) to generate history matching results and/or minimize a mismatch between the results of the one or more subsurface models and corresponding measured (i.e., field) results. The reservoir simulation performed by the third trained AI model may generate reservoir convergence criteria to increase a speed of the reservoir simulation without compromising accuracy. The reservoir convergence criteria may include dynamic changing of error tolerances for numerical solutions to be accepted including a maximum fluid saturation and composition change, a maximum pressure change, a maximum time truncation error, or a combination thereof.

The method 1100 may also include displaying results of the reservoir simulation, as at 1145.

The method 1100 may also include performing a wellsite action, as at 1150. The wellsite action may be based upon or in response to the results of the reservoir simulation. The wellsite action may be or include generating and/or transmitting a signal (e.g., using a computing system) that recommends, instructs, or causes a physical action to occur at a wellsite. The wellsite action may also or instead include performing the physical action at the wellsite. The physical action may include selecting where to drill a wellbore, drilling the wellbore, varying a weight and/or torque on a drill bit that is drilling the wellbore, varying a drilling trajectory of the wellbore, varying a concentration and/or flow rate of a fluid pumped into the wellbore, or the like.

In summary, the method 1100 may include tuning the LLM to support user help and to provide an interface for users to interact with the simulation engine. In an example, the simulation engine may have Python® extensibility. The role of the LLM may be to turn user natural language instructions into Python® code, communicate with the engine, and execute them. The method 1100 may also include autonomous features including reservoir model initialization. For example, the method 1100 may include receiving additional input parameters such as well logs, mini-test data, and core reports, and generative AI methods may extract the relevant data. An automated workflow may then be executed to initialize simulation models (see Example 1 below). The deployment of reinforcement learning may be used to support multiple proactive simulators feature. More particularly, GANs may generate realistic reservoir simulation models. In addition, they may gamify the optimization processes (e.g., field development planning and history matching) and setup reinforcement learning AI model to continuously improve based on simulation results with several objectives. Example field development planning objectives may include production maximization, CO2 sequestration volume maximization, cost minimization, or a combination thereof. In an embodiment, the simulation input parameters may be autonomously calibrated after receiving field production data (see Example 2 below).

### Example 1—Automated Reservoir Simulation Initialization

In conventional reservoir simulation workflows, users define the input to the reservoir initialization after analysing reservoir test data and wellbore measurements. For example, the user may define the interpretation of repeat formation tester (RFT) measurements of reservoir pressure and the definition of free fluid contacts. Some input may be subjective and can be biased by user experience or the project timeline. In an example, this may include the definition of multiple rock type groups as saturation functions to match initial fluid saturations derived from resistivity logs.

In proactive reservoir simulation workflows, the following technologies may be combined to automate the initialization process:
(1) Generative AI routine and special core analysis reports, sedimentology reports, . . . etc for comprehension and digitization;
(2) Machine Learning clustering algorithms to define the rock types; and/or
(3) Extensibility of reservoir simulators: programming interface to set loops, introduce variables and run an optimization processes

This may help to digitalize modelling steps, thereby speeding up the process of reservoir simulation and saving weeks of efforts spent by SMEs in interpreting and setting up simulation models. More particularly, it may standardize the process of reservoir modelling for repeatability and transparency, thereby removing human bias. It may also preserve and document the links between measured reservoir properties and simulation models.

### Step 1: Rock Quality Index (RQI) and Flow Zone Indicator (FZI)

### Let:

φᵢ: porosity
kᵢ: permeability (mDD)
FZIᵢ: flow zone indicator
RQIᵢ: rock quality index
   RQIᵢ is defined as:

$${RQI}_{i} = 0.0314 \cdot \sqrt{\frac{{k}_{i}}{{φ}_{i}}}$$

Flow zone indicator is given by:

$${FZI}_{i} = 0.0314 \cdot \frac{( 1 - {φ}_{i} ) \cdot \sqrt{{k}_{i} / {φ}_{i}}}{{φ}_{i}}$$

### Step 2: Clustering for Petrophysical Grouping

### Feature Vector:

$${x}_{i} = [ {φ}_{i} , {k}_{i} , {FZI}_{i} ]$$

Objective: Assign cluster label gᵢ∈{1, . . . , C}

### ML Clustering Example: K-Means Objective:

$${min}_{{\{ {μ}_{c} \}}_{c = 1}^{C}} {\sum }_{i = 1}^{n} {‖ {x}_{i} - {μ}_{{g}_{i}} ‖}^{2}$$

Other ML clustering algorithms that can be used: Gaussian mixture models (GMM), Hierarchical clustering—organizing maps (SOMs).

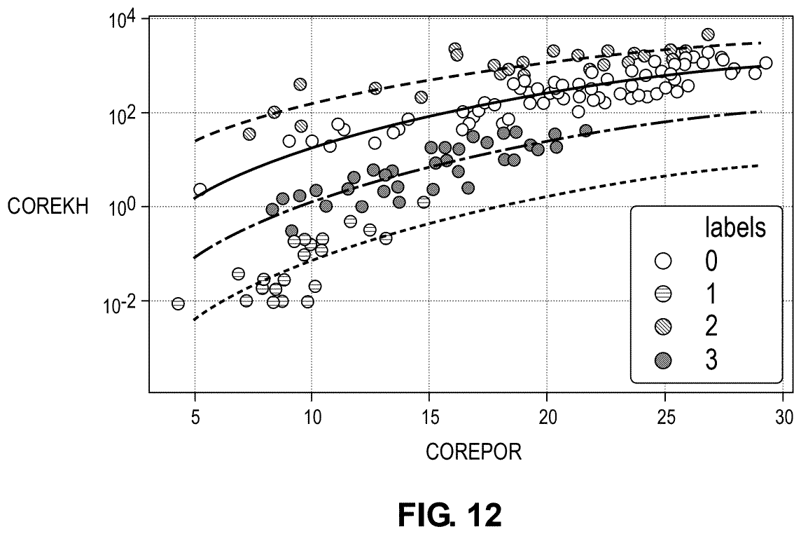

FIG. 12 illustrates a graph showing clustering based on core data, according to an embodiment. The data points represent different core plug samples for which porosity and permeability were measured. The clustering algorithm labels the plugs after the calculation of the FZI number for each plug.

### Step 3: Permeability Estimation Using Group-Based Transform

For group c:

$$log ( {k}_{i} ) = {a}_{c} + {b}_{c} \cdot log ( {φ}_{i} ) , for all i such that {g}_{i} = c$$

ML Linear Regression models can be trained on core data to get the best estimate for a_{c} and b_{c}
Or in a natural form:

$${k}_{i} = {α}_{c} \cdot {φ}_{i}^{{β}_{c}} , where {α}_{c} = {e}^{{a}_{c}} , {β}_{c} = {b}_{c}$$

For cells away from cored wells: at cell j with φⱼ and predicted group gⱼ=c, the permeability can be calculated as:

$$= {α}_{c} \cdot {φ}_{j}^{{β}_{c}}$$

### Step 4: Pressure-Depth Gradient and Contact Determination

$$p ( z ) = {p}_{r e f} + {p}_{f} \cdot g \cdot ( z - {z}_{r e f} )$$

Gradient from regression:
pᵢ=a_{f}+b_{f}·zᵢ, where f denotes the fluid which could oil, water or gas.
Contact depths can then be calculated as:

$$\begin{matrix}{z}_{OWC} = \frac{( {a}_{water} - {a}_{o i l} )}{( {b}_{o i l} - {b}_{water} )} \\ {z}_{G O C} = \frac{( {a}_{o i l} - {a}_{g a s} )}{( {b}_{g a s} - {b}_{o i l} )}\end{matrix}$$

Well logs can be used to aid in defining the depth span for oil, water and gas phases.
Step 5: Saturation-Height Modeling with J-Function Scaling
The J function can be calculated for wells with measurement data:

$$J ( {S}_{w} ) = \frac{{p}_{c} ( {S}_{w} ) \cdot \sqrt{k}}{σ \cdot cos ( θ ) \cdot φ}$$

Using a different expression for pc, the saturations can be back-calculated as:

$${S}_{w} ( h ) = {J}^{- 1} ( \frac{ρ g h \sqrt{k}}{σ cos ( θ ) φ} )$$

For a rock-type-specific model:

$${S}_{w}^{( c )} ( h ) = {f}_{c} ( \frac{h \cdot \sqrt{{k}_{j}}}{{φ}_{j}} )$$

The back calculation of S_{w} using the transform shape parameters per rock type and the fluid contacts may be determined iteratively in an optimization loop. The objective of the optimization is to minimize the difference between calculated and observed saturations and pressures. For example:

$${min}_{θ , FWL} \sum {( {S}_{w}^{( {c}_{j} )} ( {h}_{j} ; θ ) - )}^{2}$$

### Step 6: Machine Learning for Rock Typing in Uncored Wells

For cored wells, for each depth point i:

$$Feature vector {x}_{i} = [ log {1}_{i} , log {2}_{i} , … , log {n}_{i} ]$$

Target label: gᵢ∈{1, 2, . . . , C}
   Train classifier M: x→g on cored well data, where M represent a Machine Learning model such as Decision Trees, Random Forests, Gradient Boosting or Neural Networks.
   For uncored depth j:

$${\hat{g}}_{j} = M ( {x}_{j} )$$

Then assign:

$$= \cdot {φ}_{j}^{{β}_{{\hat{g}}_{J}}}$$

$${\hat{S}}_{w} , j ( h ) = {f}_{{\hat{g}}_{j}} ( \frac{h \cdot \sqrt{{\hat{k}}_{j}}}{{φ}_{j}} )$$

kr_{w,j}(S_{w}), kr_{o,j}(S_{w}), pcⱼ(S_{w}) from a group-specific library.
Type equation here.

### Example 2 Autonomous History Matching

As discussed previously, model calibration and/or history matching can occupy the greatest time in a field development planning project. This is because it is an inverse problem that is normally solved using a trial-and-error approach.

In a proactive reservoir simulation workflow, the simulator can auto calibrate the input in a way that the full physics simulation results match the field observations. The following techniques may be combined to execute the workflow:
1. GAN models to generate multiple models for the continuous training of the foundation model; and
2. Reinforcement learning where input data is purposedly hidden to train the foundation model on tuning process to get better history matching results.

This may help to digitalize modelling steps, thereby speeding up the process of reservoir simulation, and saving months of efforts spent by SMEs in history matching.

### Step 1: Generative Model Creation Using GANs

Let mᵢ=G(zᵢ) be a reservoir model generated from noise input zᵢ using the GAN generator G.
G(z; θ_G): Generator network.
D(m; θ_D): Discriminator network.
The GAN is trained by solving:

$${min}_{{θ}_{G}} {max}_{{θ}_{D}} {E}_{\{ m ∼ {M}_{real} \}} [ log D ( m ) ] + {E}_{\{ z ∼ N ( 0 , I ) \}} [ log ( 1 - D ( G ( z ) ) ) ]$$

### Step 2: Run Simulations on Generated Models

For each generated model mᵢ=G(zᵢ), simulate production response:
yᵢ=S(mᵢ, u), where u is a fixed control vector (e.g., well types, rates).
   This generates a dataset {(mᵢ, yᵢ)} for reinforcement learning.

### Step 3: Reinforcement Learning for History Matching

State sₜ: Encodes mismatch and current model status.
Action aₜ: Modifies model (e.g., permeability, facies index).
Transition sₜ₊₁: New state after simulation on modified model.
Reward rₜ=−Loss(yₜ, y_{obs}), where Loss is often mean squared error.
Objective: Train policy π(aₜ|sₜ; θ) to maximize expected cumulative reward.

### Exemplary Computing System

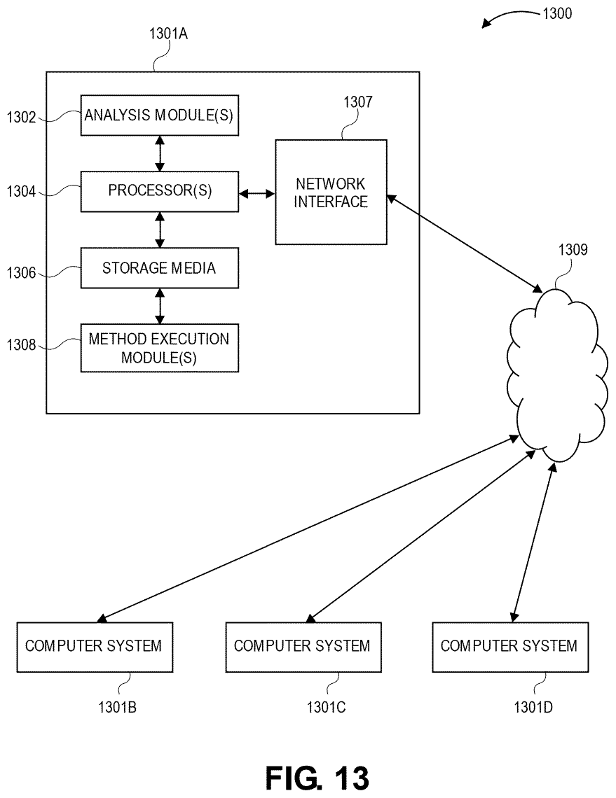

In some embodiments, the methods of the present disclosure may be executed by a computing system. FIG. 13 illustrates an example of such a computing system 1300, in accordance with some embodiments. The computing system 1300 may include a computer or computer system 1301A, which may be an individual computer system 1301A or an arrangement of distributed computer systems. The computer system 1301A includes one or more analysis modules 1302 that are configured to perform various tasks according to some embodiments, such as one or more methods disclosed herein. To perform these various tasks, the analysis module 1302 executes independently, or in coordination with, one or more processors 1304, which is (or are) connected to one or more storage media 1306. The processor(s) 1304 is (or are) also connected to a network interface 1307 to allow the computer system 1301A to communicate over a data network 1309 with one or more additional computer systems and/or computing systems, such as 1301B, 1301C, and/or 1301D (note that computer systems 1301B, 1301C and/or 1301D may or may not share the same architecture as computer system 1301A, and may be located in different physical locations, e.g., computer systems 1301A and 1301B may be located in a processing facility, while in communication with one or more computer systems such as 1301C and/or 1301D that are located in one or more data centers, and/or located in varying countries on different continents).

A processor may include a microprocessor, microcontroller, processor module or subsystem, programmable integrated circuit, programmable gate array, or another control or computing device.

The storage media 1306 may be implemented as one or more computer-readable or machine-readable storage media. Note that while in the example embodiment of FIG. 13 storage media 1306 is depicted as within computer system 1301A, in some embodiments, storage media 1306 may be distributed within and/or across multiple internal and/or external enclosures of computing system 1301A and/or additional computing systems. Storage media 1306 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 1300 contains one or more method execution module(s) 1308. In the example of computing system 1300, computer system 1301A includes the method execution module 1308. In some embodiments, a single method execution module may be used to perform some aspects of one or more embodiments of the methods disclosed herein. In other embodiments, a plurality of method execution modules may be used to perform some aspects of methods herein.

It should be appreciated that computing system 1300 is merely one example of a computing system, and that computing system 1300 may have more or fewer components than shown, may combine additional components not depicted in the example embodiment of FIG. 13, and/or computing system 1300 may have a different configuration or arrangement of the components depicted in FIG. 13. The various components shown in FIG. 13 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 1300, FIG. 13), and/or through manual control by a user who may make determinations regarding whether a given step, action, template, model, or set of curves has become sufficiently accurate for the evaluation of the subsurface three-dimensional geologic formation under consideration.

The foregoing description, for purposes of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for performing a reservoir simulation, the method comprising:
receiving input data;
generating one or more subsurface models based upon the input data;
training a first artificial intelligence (AI) model based upon the one or more subsurface models to produce a first trained AI model;
training a second AI model by hiding some of the input data to produce a second trained AI model;
training a third AI model to produce a third trained AI model, wherein the third AI model is trained using simulation performance metrics from simulations performed to train the first AI model and the second AI model; and
performing the reservoir simulation using the first trained AI model, the second trained AI model, and/or the third trained AI model.

2. The method of claim 1, wherein the input data comprises realistic reservoir and field data including well production data, pressure data, and field development history data related to active and decommissioned projects.

3. The method of claim 2, wherein the input data also comprises realistic reservoir properties distribution data, fault data, well geometries data, completion data, fluid data, and core analysis data

4. The method of claim 1, wherein the one or more subsurface models comprise a set of real and simulated subsurface models, and wherein the simulated subsurface models are generated using a generative adversary network (GAN) model.

5. The method of claim 4, wherein the first AI model is trained based upon data generated by the real and simulated subsurface models, wherein the first AI model is trained with different field development options using gamified reinforcement learning.

6. The method of claim 5, wherein the different field development options comprise adding infill production and/or injection wells, testing workover options through completion zone shut-offs or new zone perforations, and optimizing production and injection rates.

7. The method of claim 1, wherein the simulation performance metrics comprise a total time of the simulations, an average length of time-steps in the simulations, a number of chopped time-steps in the simulations, and a total number of linear and nonlinear iterations of the simulations.

8. The method of claim 1, wherein the reservoir simulation is performed using the first trained AI model, the second trained AI model, and the third trained AI model.

9. The method of claim 1, further comprising generating and displaying results of the reservoir simulation.

10. The method of claim 1, further comprising performing a physical action in response to results of the reservoir simulation.

11. A computing system, comprising:
one or more processors; and
a memory system comprising one or more non-transitory computer-readable media storing instructions that, when executed by at least one of the one or more processors, cause the computing system to perform operations, the operations comprising:
receiving input data, wherein the input data comprises realistic reservoir and field data including well production data, pressure data, and/or field development history data related to active and decommissioned projects, and wherein the input data also comprises realistic reservoir properties distribution data, fault data, well geometries data, completion data, fluid data, or core analysis data;
generating one or more subsurface models based upon the input data, wherein the one or more subsurface models comprise a set of real and simulated subsurface models;
training a first artificial intelligence (AI) model based upon the one or more subsurface models to produce a first trained AI model, wherein the first AI model is trained based upon data generated by the real and simulated subsurface models;
training a second AI model to produce a second trained AI model, wherein the second AI model is trained by hiding some of the input data;
training a third AI model to produce a third trained AI model, wherein the third AI model is trained using simulation performance metrics from simulations performed to train the first AI model and the second AI model; and
performing the reservoir simulation using the first trained AI model, the second trained AI model, and the third trained AI model.

12. The computing system of claim 11, wherein the reservoir simulation performed by the first trained AI model generates autonomous field development output used for production forecasting, increasing production, and/or cost reduction.

13. The computing system of claim 11, wherein the reservoir simulation performed by the second trained AI model uses results of the one or more subsurface models that are obtained using gamified reinforcement learning to generate history matching results and/or minimize a mismatch between the results of the one or more subsurface models and corresponding measured results.

14. The computing system of claim 11, wherein the reservoir simulation performed by the third trained AI model generates reservoir convergence criteria to increase a speed of the reservoir simulation without compromising accuracy.

15. The computing system of claim 14, wherein the reservoir convergence criteria comprises dynamic changing of error tolerances for numerical solutions to be accepted including a maximum fluid saturation and composition change, a maximum pressure change, and a maximum time truncation error.

16. A non-transitory computer-readable medium storing instructions that, when executed by one or more processors of a computing system, cause the computing system to perform operations, the operations comprising:
receiving first input data, wherein the first input data comprises user manuals, technical descriptions, sample reservoir simulation input files, and sample reservoir simulation output files;
tuning a large language model (LLM) based upon the first input data to produce a tuned LLM, wherein the LLM is tuned to develop natural language support for interactivity with a reservoir simulation engine;
receiving second input data, wherein the second input data comprises realistic reservoir and field data including well production data, pressure data, and field development history data related to active and decommissioned projects, and wherein the second input data also comprises realistic reservoir properties distribution data, fault data, well geometries data, completion data, fluid data, and core analysis data;
generating one or more subsurface models using the tuned LLM based upon the second input data, wherein the one or more subsurface models comprise a set of real and simulated subsurface models, and wherein the simulated subsurface models are generated using a generative adversary network (GAN) model or other artificial intelligence techniques;
training a first artificial intelligence (AI) model based upon the one or more subsurface models to produce a first trained AI model, wherein the first AI model is trained based upon data generated by the real and simulated subsurface models, wherein the first AI model is trained with different field development options using gamified reinforcement learning, and wherein the different field development options comprise adding infill production and/or injection wells, testing workover options through completion zone shut-offs or new zone perforations, and optimizing production and injection rates;
training a second AI model to produce a second trained AI model, wherein the second AI model is trained by hiding some of the second input data;
training a third AI model to produce a third trained AI model, wherein the third AI model is trained using simulation performance metrics from simulations performed to train the first AI model and the second AI model, and wherein the simulation performance metrics comprise a total time of the simulations, an average length of time-steps in the simulations, a number of chopped time-steps in the simulations, and a total number of linear and nonlinear iterations of the simulations;
performing the reservoir simulation using the first trained AI model, the second trained AI model, and the third trained AI model,
wherein the reservoir simulation performed by the first trained AI model generates autonomous field development output used for production forecasting, increasing production, and/or cost reduction,
wherein the reservoir simulation performed by the second trained AI model uses results of the one or more subsurface models that are obtained using gamified reinforcement learning to generate history matching results and/or minimize a mismatch between the results of the one or more subsurface models and corresponding measured results, and
wherein the reservoir simulation performed by the third trained AI model generates reservoir convergence criteria to increase a speed of the reservoir simulation without compromising accuracy, and wherein the reservoir convergence criteria comprises dynamic changing of error tolerances for numerical solutions to be accepted including a maximum fluid saturation and composition change, a maximum pressure change, and a maximum time truncation error.

17. The non-transitory computer-readable medium of claim 16, wherein the operations further comprise displaying results of the reservoir simulation.

18. The non-transitory computer-readable medium of claim 16, wherein the operations further comprise performing a wellsite action in response to the results.

19. The non-transitory computer-readable medium of claim 18, wherein the wellsite action comprises generating and/or transmitting a signal that recommends, instructs, or causes a physical action to occur at a wellsite.

20. The non-transitory computer-readable medium of claim 19, wherein the physical action comprises adjusting a pressure in one or more wells using a pump at a surface, adjusting a flow rate into and/or out of the one or more wells using the pump, selecting where to drill a new well, drilling the new well, varying a weight and/or torque on a drill bit that is drilling the new well, varying a drilling trajectory of the new well, or varying a concentration and/or flow rate of a fluid pumped into the new well.
